(19) United States
(12) Patent Application Publication
(10) Pub. No.: US 2024/0313774 A1
(43) Pub. Date: Sep. 19, 2024

(54) Cryogenic Analog Switch Circuit

(71) Applicant: The United States of America, as represented by the Secretary of the Navy, San Diego, CA (US)

(72) Inventors: Sergio A. Montoya, Chula Vista, CA (US); Anna M. Leese de Escobar, Encinitas, CA (US)

(21) Appl. No.: 18/185,051

(22) Filed: Mar. 16, 2023

(51) Int. Cl. H03K 17/92; H10N 60/84

(52) U.S. Cl. CPC H03K 17/92; H10N 60/84

(57) ABSTRACT

A cryogenic analog switch circuit includes a magnetic strip and a superconductor strip. The magnetic strip generates a first and second magnetic domain separated by a domain wall. In response to a current through the magnetic strip, the domain wall moves to change respective extents of the first and second magnetic domains within the magnetic strip. The superconductor strip is disposed adjacent the magnetic strip for undergoing a phase transition switching between a superconducting state and a normal state in response to a magnetic field controlled by the respective extents of the first and second magnetic domains within the magnetic strip.

### FEDERALLY SPONSORED RESEARCH AND DEVELOPMENT

The United States Government has ownership rights in this invention. Licensing and technical inquiries may be directed to the Office of Research and Technical Applications, Naval Information Warfare Center Pacific, Code 72120, San Diego, CA, 92152; voice (619) 553-5118; NIWC_Pacific_T2@us.navy.mil. Reference Navy Case Number 110348.

### BACKGROUND OF THE INVENTION

Superconducting electronics are attractive for developing high energy efficiency, high sensitivity, and high speed technologies because they exhibit zero resistance when a direct current is applied and very low energy dissipation for an alternating current. Logic devices based on superconducting Josephson junctions have achieved clocking speeds of up to 300 GHz for on-chip interconnections and up to 60 GHz for chip-to-chip connections.

However, the development of complex, integrated, and high-speed superconducting electronics has not been realized due to a lack of a highly scalable and high-speed cryogenic analog switch, which is an essential building block for making a wide range of technologies.

Buck, D. A. “The Cryotron-a Superconductive Computer Component.” Proceedings of the IRE 44.4 (1956): 482-493, discloses two superconducting materials with different critical temperatures (Tc) separated by an insulating layer. When the lower Tc material is wrapped around a straight insulated wire of the higher Tc material, and the device is cooled, the supercurrents flowing in the lower Tc wrapping can be attenuated by applying a current in the higher Tc wire to generate a magnetic field, which causes the lower Tc wrapping to undergo a phase change from the superconducting state to the normal state. However, this wrapped wire is not scalable for integrated circuit applications.

McCaughan, Adam N., et al. “A Superconducting-Nanowire Three-Terminal Electrothermal Device.” Nano letters 14.10 (2014): 5748-5753, proposed a planar and compact device, which locally heats a region of superconducting wire across which supercurrents flow. This heat causes a local region, at the three-terminal intersection, of the superconducting material to transition from the superconducting state to the normal state. This device could facilitate low-speed superconducting technologies; however, it does not facilitate high-speed technologies due to the thermal inertia of the cooling process for returning the superconducting material to the superconducting state. Furthermore, introducing heat into a superconducting circuit reduces energy efficiency.

### SUMMARY OF THE INVENTION

A cryogenic analog switch circuit includes a magnetic strip and a superconductor strip. The magnetic strip generates a first and second magnetic domain separated by a domain wall. In response to a current through the magnetic strip, the domain wall moves to change respective extents of the first and second magnetic domains within the magnetic strip. The superconductor strip is disposed adjacent the magnetic strip for undergoing a phase transition switching between a superconducting state and a normal state in response to a magnetic field controlled by the respective extents of the first and second magnetic domains within the magnetic strip.

### BRIEF DESCRIPTION OF DRAWINGS

Throughout the several views, like elements are referenced using like references. The elements in the figures are not drawn to scale and some dimensions are exaggerated for clarity.

FIG. 1A-C are perspective views of a cryogenic analog switch circuit in respective states in accordance with an embodiment of the invention.

FIG. 2A-C are cross-sectional views through the cryogenic analog switch circuit of FIG. 1A-C in the respective states.

FIG. 3A-B are perspective views of a cryogenic analog switch circuit in respective states in accordance with an embodiment of the invention.

FIG. 4A-B are perspective views of a cryogenic analog switch circuit in respective states in accordance with an embodiment of the invention.

### DETAILED DESCRIPTION

The disclosed systems below may be described generally, as well as in terms of specific examples and/or specific embodiments. For instances where references are made to detailed examples and/or embodiments, it should be appreciated that any of the underlying principles described are not to be limited to a single embodiment, but may be expanded for use with any of the other methods and systems described herein as will be understood by one of ordinary skill in the art unless otherwise stated specifically.

Embodiments of the invention disclose a solid-state electronic device capable of attenuating and/or stopping the flow of either low or high amplitude supercurrents in geometrically confined structures, such as patterned wires, made from a superconducting material. The device uses the magnetic fields that emanate from magnetic domains to modulate/attenuate the amplitude of supercurrents that are transmitted across a superconductor material. Varying the applied magnetic fields is realized by electrically manipulating the magnetic domains in the magnetic element. This facilitates the realization of a new integrated cryogenic analog switch for superconducting electronics based on low and/or high temperature superconducting materials.

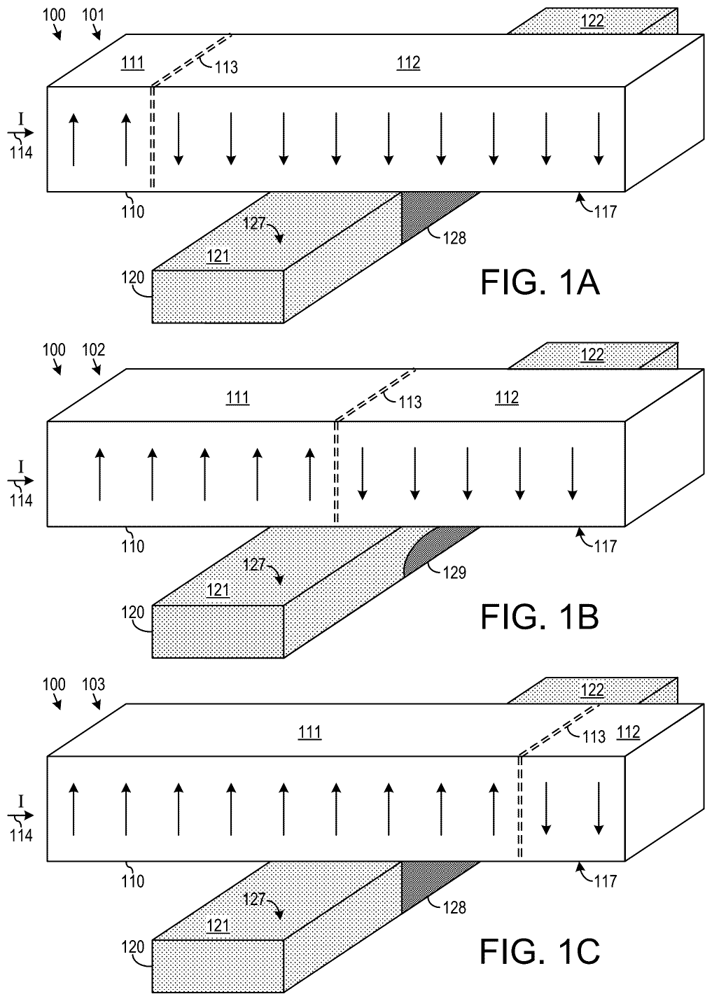

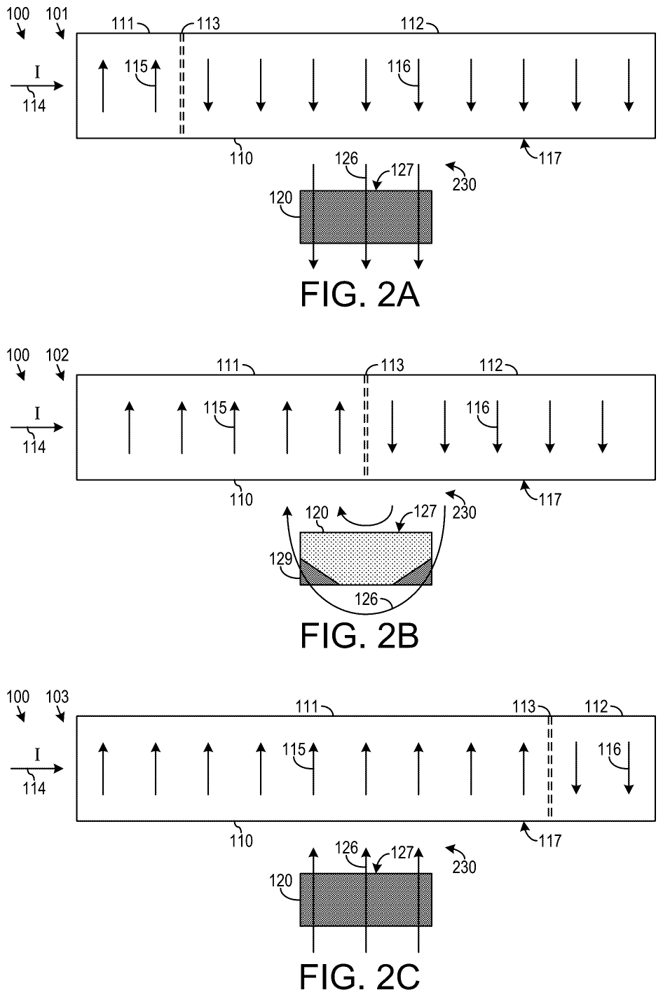

FIG. 1A-C are perspective views of a cryogenic analog switch circuit 100 in respective states 101, 102, and 103 in accordance with an embodiment of the invention. FIG. 2A is a cross-sectional view through the cryogenic analog switch circuit 100 of FIG. 1A in the state 101. FIG. 2B is a cross-sectional view through the cryogenic analog switch circuit 100 of FIG. 1B in the state 102. FIG. 2C is a cross-sectional view through the cryogenic analog switch circuit 100 of FIG. 1C in the state 103.

The cryogenic analog switch circuit 100 includes a magnetic strip 110 and a superconductor strip 120. The magnetic strip 110 generates a first magnetic domain 111 and a second magnetic domain 112 separated by a domain wall 113. Example materials for the magnetic strip 110 include ferromagnetic materials, antiferromagnetic materials, and ferrimagnetic materials. The superconductor strip 120 is disposed adjacent the magnetic strip 110. As defined in the specification and claims, a superconductor means a material that becomes superconducting upon cooling below a critical temperature. However, the superconductor strip 120 need not be presently cooled below the critical temperature; the superconductor strip 120 merely needs to be capable of becoming superconducting upon sufficient intended cooling. Superconductor materials include low temperature and high temperature superconductors and also include Type I and Type II superconductors. Of course, the superconductor strip 120 is actually superconducting during switching of the cryogenic analog switch circuit 100 into and out of a superconducting state as discussed below.

In response to a current 114 through the magnetic strip 110, the domain wall 113 moves as shown in FIG. 1A-C. FIG. 1A shows a first state 101 for the domain wall 113, FIG. 1B shows a second state 102 for the domain wall 113 after the domain wall 113 is moved by current 114, and FIG. 1C shows a third state 103 for the domain wall 113 after the domain wall 113 is moved farther by current 114. If the direction of current 114 is reversed, the domain wall 113 moves in the opposite direction. Thus, the sequence of states 101, 102, and 103 show in FIG. 1A-C is reversible. In the absence of any current 114, each of states 101, 102, and 103 is preserved. For example, if current 114 is turned off, the existing state is preserved regardless of whether this existing state is state 101, 102, or 103 or another intermediate state. Thus, the existing state of the domain wall 113 of the magnetic strip 110 forms a non-transitory memory.

Example mechanisms for the current 114 moving the domain wall 113 through the magnetic strip 110 include spin-transfer torque and spin-orbit torque. It will be appreciated that the direction of movement of the domain wall 113 depends upon the domain wall chirality and the spin torque mechanism. Thus, the direction of current 114 shown in FIG. 1A-C corresponds to the current direction that moves the domain wall 113 to the right in FIG. 1A-C. Depending upon domain wall chirality, the actual current direction might be opposite the arrow shown for current 114 in FIG. 1A-C. Typically, the current 114 includes current pulses for appropriately moving the domain wall 113 through the magnetic strip 110, with these current pulses separated by quiescent periods in which the present state 101, 102, or 103 of the domain wall 113 is preserved to form a non-transitory and persistent memory.

The magnetic strip 110 includes multiple layers in one embodiment, such as an outer layer of platinum and an inner layer of a ferromagnetic material adjacent the superconductor strip 120, with the platinum layer generating a spin current with a spin-orbit torque exerting a torque on the magnetic moments of the domain wall 113 in the ferromagnetic layer. This pushes the domain wall 113 through the ferromagnetic layer at a speed dependent upon the applied current density of the current 114 and the overall magnetic properties of the magnetic strip 110. The magnetic strip 110 is usually realized using amorphous and/or crystal materials in the form of thin films and/or thin-film multilayers and/or bulk materials using a combination of transition metals and/or rare earth metals.

As the current 114 moves the domain wall 113, respective extents change for the first and second magnetic domains 111 and 112. In FIG. 1A, the respective extent for the magnetic domain 111 is small and the respective extent for the magnetic domain 112 is large. Thus, as shown in FIG. 2A, the magnetic field 126 through the superconductor strip 120 is induced almost entirely from the magnetic moment 116 of the nearby and dominate magnetic domain 112. In FIG. 1B and FIG. 2B, the respective extents are balanced for the first and second magnetic domains 111 and 112. Thus, as shown in FIG. 2B, the magnetic field 126 through the superconductor strip 120 balances the different magnetic moments 115 and 116 of the magnetic domains 111 and 112, respectively. In FIG. 1C, the respective extent for the magnetic domain 111 is large and the respective extent for the magnetic domain 112 is small. Thus, as shown in FIG. 2C, the magnetic field 126 through the superconductor strip 120 is induced almost entirely from the magnetic moment 115 of the nearby and dominate magnetic domain 111.

Typically, the different magnetic moments 115 and 116 of the magnetic domains 111 and 112 are opposing magnetic moments 115 and 116 directed in opposite directions. Thus, when the respective extents are balanced for the first and second magnetic domains 111 and 112 as shown in FIG. 2B, these balanced opposing magnetic moments 115 and 116 tend to cancel each other at the superconductor strip 120, resulting in a weak magnetic field 126 at the superconductor strip 120. In contrast as shown in FIGS. 2A and 2C, an enhanced magnetic field 126 results when a single magnetic moment 116 or 115 dominates.

A superconductor transitions from a normal resistive state to a superconducting state upon cooling the superconductor below the critical temperature for the superconductor. However, a magnetic field at a superconductor in the superconducting state can transition the superconductor back into the normal state, especially when the operating temperature of the superconductor is slightly below its critical temperature. In general, the superconducting state can be modulated under an applied magnetic field when the amplitude of the magnetic field exceeds a critical value, known as the critical field, and then the superconducting state ceases to exist. Superconductor materials are classified in two classes (Type I and Type II) which denote the number of critical fields present in the material. The dipole magnetic fields of the magnetic strip 110 are engineered to generate the critical field(s) for the superconducting material of the superconductor strip 120.

In FIG. 2A, the magnetic field 126 through the superconductor strip 120 has a strength sufficient strength to switch the superconductor strip 120 from the superconducting state into the normal state. This is indicated in FIG. 2A with the dark shading of the superconductor strip 120. However, the magnetic field 126 has a strength sufficient strength to switch the superconductor strip 120 into the normal state only for a portion 128 of the superconductor strip 120 directly underneath the magnetic strip 110 as shown in FIG. 1A. In contrast, the two terminal ends 121 and 122 of the superconductor strip 120 remain in the superconducting state. However, a non-zero resistance would be measured between the terminal ends 121 and 122 due to the resistance of the portion 128 of the superconductor strip 120 in the normal state. In summary, FIG. 1A and FIG. 2A illustrate the cryogenic analog switch circuit 100 is open with the superconductor strip 120 in the resistive normal state 101.

As the current 114 pushes the domain wall 113 from the state 101 shown in FIG. 2A to the state 102 shown in FIG. 2B, the superconductor strip 120 undergoes a phase transition switching from the superconducting state of the dark shading of FIG. 1A and FIG. 2A to the normal state of the light shading of FIG. 1B and FIG. 2B. The superconductor strip 120 undergoes the phase transition switching from the superconducting state to the normal state in response to the magnetic field 126 controlled by the respective extents of the first and second magnetic domains 111 and 112 within the magnetic strip 110. FIG. 1B and FIG. 2B illustrate the possible scenario that some portion 129 of the superconductor strip 120 underneath the magnetic strip 110 remains in the normal state; however, a zero or near-zero resistance would be measured between the terminal ends 121 and 122 because a continuous path exists through the superconducting state of the light shading. In summary, FIG. 1B and FIG. 2B illustrate the cryogenic analog switch circuit 100 is closed when the superconductor strip 120 in the superconducting state 102.

As the current 114 pushes the domain wall 113 farther from the state shown in FIG. 2B to the state shown in FIG. 2C, the superconductor strip 120 undergoes another phase transition switching from the normal state of the light shading of FIG. 1B and FIG. 2B to the superconducting state of the dark shading of FIG. 1C and FIG. 2C in response to the magnetic field 126 controlled by the respective extents of the first and second magnetic domains 111 and 112 within the magnetic strip 110. In summary, FIG. 1C and FIG. 2C illustrate the cryogenic analog switch circuit 100 is open when the superconductor strip 120 in the resistive normal state 103.

In one embodiment, the domain wall 113 moves in response to the current 114 through the magnetic strip 110 at a speed measured in up to kilometers per second, and a distance the domain wall 113 moves to accomplish switching the superconductor strip between the superconducting state 102 and the normal state 101 or 103 is measured in tens of nanometers, such that a transition time from the normal state 101 to the superconducting state 102 and another transition time from the superconducting state 102 to the normal state 103 are each measured in tens of picoseconds.

FIG. 2A-C illustrate a gap 230 between the magnetic strip 110 and the superconductor strip 120. Note that for clarity this gap does not exist in FIG. 1A-C. Typically, the cryogenic analog switch circuit includes an insulator (not shown) disposed in the gap 230 between the magnetic strip 110 and the superconductor strip 120 for electrically and thermally isolating the magnetic strip 110 and the superconductor strip 120 from each other. Preferably, this insulator has a low magnetic susceptibility.

The superconductor strip 120 spans between two terminal ends 121 and 122 as shown in FIG. 1A-C. A voltage across the two terminal ends 121 and 122 is zero when the cryogenic analog switch circuit 100 is closed with the superconductor strip 120 in the superconducting state 102 of FIG. 1B. The voltage across the two terminal ends 121 and 122 is non-zero when the cryogenic analog switch circuit 100 is open with the superconductor strip 120 in the normal state 101 or 103 of FIG. 1A and FIG. 1C. The superconducting state 102 and the normal states 101 and 103 of the superconductor strip 120 are each maintained stored within the cryogenic analog switch circuit 100 as long as the current 114 through the magnetic strip 110 is zero current.

In one embodiment, the magnetic strip 110 is uniaxially anisotropic to predispose the first and second magnetic domains 111 and 112 becoming magnetized in opposite directions perpendicular to a major face 117 of the magnetic strip 110. The major face 117 of the magnetic strip 110 is disposed adjacent a major face 127 of the superconductor strip 120. The magnetic strip 110 crosses the superconductor strip 120 with a first and second overhang beyond the major face 127 of the superconductor strip 120. While the first magnetic domain 111 predominates across the face 117 of the magnetic strip 110, the domain wall 113 is disposed within the second overhang of the magnetic strip 110 as shown in FIG. 1C. While the second magnetic domain 112 predominates across the major face 117 of the magnetic strip 110, the domain wall 113 is disposed within the first overhang of the magnetic strip 110 as shown in FIG. 1A.

In another embodiment, the magnetic strip 110 possesses in-plane magnetization or any intermediate magnetization state between perpendicular and in-plane states. The magnetic element generally provides at least two magnetic domains with opposite magnetization separated by a magnetic domain wall. For example, the magnetic strip 110 and the superconductor strip 120 are arranged side-by-side on a planar substrate, and the magnetic domains generate in-plane dipole magnetic fields emanating from the sides of the magnetic element and these in-plane dipole magnetic fields are laterally coupled through the superconductor strip 120.

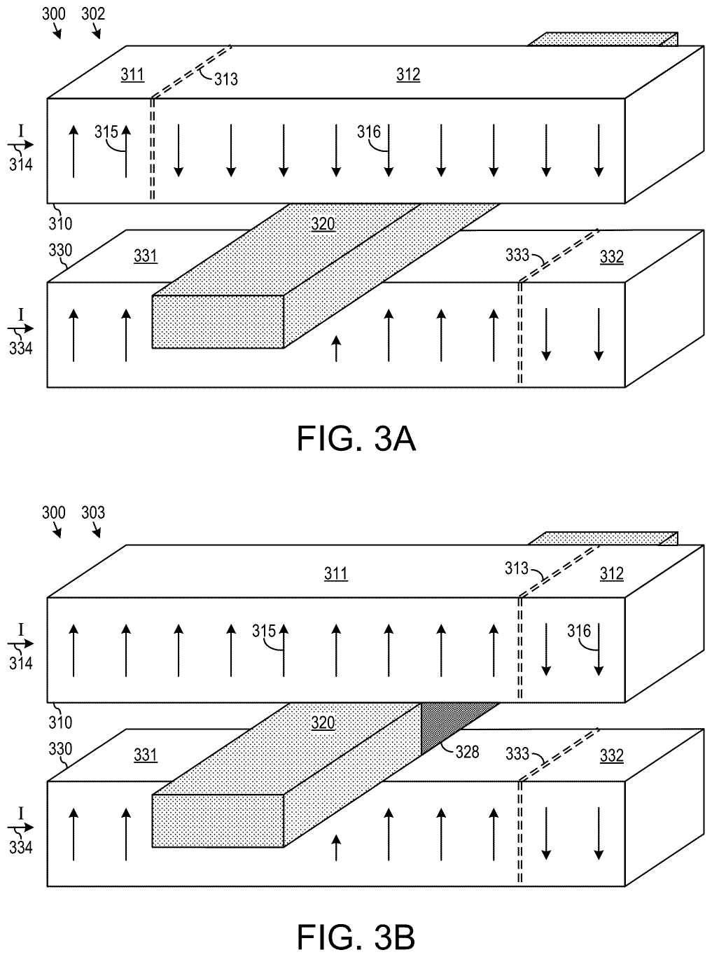

FIG. 3A-B are perspective views of a cryogenic analog switch circuit 300 in respective states 302 and 303 in accordance with an embodiment of the invention. FIG. 3A-B shows two magnetic strips 310 and 330 sandwiching the superconductor strip 320. The two magnetic strips 310 and 330 have the same or different compositions in embodiments of the invention. Typically, the superconductor strip 320 is separated from the magnetic strips 310 and 330 by insulating layers not shown in FIG. 3A-B.

The embodiment of FIG. 3A-B is preferred over the embodiment of FIG. 1A-C because the superconducting state 102 of FIG. 1B requires a domain wall 113 that becomes nearly perfectly centered over the superconductor strip 120 with a low tolerance for misalignment. In contrast, the embodiment of FIG. 3A-B merely requires that the domain wall 313 is not near the superconductor strip 320 in each of superconducting state 302 of FIG. 3A and the normal state 303 of FIG. 3B.

The magnetic strip 310 generates a first magnetic domain 311 and a second magnetic domain 312 separated by a domain wall 313. The respective extents of the magnetic domains 311 and 312 together span a length of the magnetic strip 310. A current 314 in a first direction along the length moves the domain wall 313 of FIG. 3A until the first magnetic domain 311 nearly spans the length of the magnetic strip 310 as shown in FIG. 3B. Reversibly, the current 314 in an opposite second direction along the length moves the domain wall 313 of FIG. 3B until the second magnetic domain 312 nearly spans the length of the magnetic strip 310 as shown in FIG. 3A.

In one embodiment, the second magnetic strip 330 constitutes a magnetic bias for opposing the magnetic moment 316 of the magnetic domain 312 of the first magnetic strip 310 as shown in FIG. 3A, and for supporting the magnetic moment 315 of magnetic domain 311 of the first magnetic strip 310 as shown in FIG. 3B. In FIG. 3A, the magnetic domain 312 nearly spanning the length of the first magnetic strip 310 and the magnetic bias from the second magnetic strip 330 together generate a magnetic field having a diminished strength because the magnetic bias opposes the magnetic domain 312. In FIG. 3B, the magnetic domain 311 nearly spanning the length of the magnetic strip 310 and the magnetic bias together generate the magnetic field having an enhanced strength because the magnetic bias supports the magnetic domain 311.

As shown in FIG. 3A, when the current 314 moves the domain wall 313 so that the respective extent of the magnetic domain 312 predominates across the major face of the magnetic strip 310, the superconductor strip 320 adopts the superconductive state 302 because the magnetic domain 312 causes the magnetic field at the superconductor strip 320 to have a weak strength that does not penetrate through the superconductor strip 320. The magnetic field having the diminished strength at the superconductor strip 320 switches the superconductor strip 320 into the superconducting state 302.

As shown in FIG. 3B, when the current 314 moves the domain wall 313 so that the respective extent of the magnetic domain 311 predominates across the major face of the magnetic strip 310, the superconductor strip 320 adopts the normal state 303 because the magnetic domain 311 causes the magnetic field at the superconductor strip 320 to have an enhanced strength that penetrates through the superconductor strip 320 and destroys the superconductive state 302 for a portion 328 of the superconductor strip 320 directly beneath the magnetic strip 310. The magnetic field having the enhanced strength at the superconductor strip 320 switches the superconductor strip 320 into the normal state 303.

In an embodiment not shown, the second magnetic strip 330 is a uniformly magnetized permanent magnet providing a magnetic moment with a strength equaling each of the magnetic moments 315 and 316 of the magnetic domains 311 and 312 of the first magnetic strip 310.

In the preferred embodiment shown in FIG. 3A-B, the second magnetic strip 330 has an identical and symmetrical composition to the first magnetic strip 310. Typically in this embodiment, both magnetic strips 310 and 330 are uniaxially anisotropic to predispose their magnetic domains becoming magnetized in opposite directions perpendicular to a major face of each magnetic strip 310 or 330. This ensures balanced magnetic moments directed towards the superconductor strip 320 despite variations in the fabrication process and the operating conditions when, as shown in FIG. 3A, the magnetic moment 316 of the magnetic strip 310 opposes the magnetic moment of the magnetic strip 330. These balanced opposing magnetic moments tend to cancel each other at the superconductor strip 320, resulting in a weak magnetic field at the superconductor strip 320. Due to the weak magnetic field, superconductor strip 320 adopts the superconducting state 302.

Thus, the superconductor strip 320 is in the superconducting state 302 under the weak magnetic field driven from the magnetic domain 312 while the magnetic domain 312 nearly spans the length of the magnetic strip 310 as shown in FIG. 3A. The superconductor strip 320 is in the normal state 303 under the enhanced magnetic field driven from the magnetic domain 311 while the magnetic domain 311 nearly spans the length of the magnetic strip 310 as shown in FIG. 3B.

The superconductor strip 320 switches between the superconducting state 302 and the normal state 303 in response to the magnetic field at the superconductor strip 320 switching between weak and enhanced states in response to the domain wall 313 moving in response to the current 314 through the magnetic strip 310, with the weak state arising more from the magnetic domain 312 than the magnetic domain 311 and the enhanced state arising more from the magnetic domain 311 than the magnetic domain 312. Thus, the superconductor strip 320 switches between the superconducting state 302 and the normal state 303 in response to the magnetic field at the superconductor strip 320 switching between predominately arising from the respective extent of the magnetic domain 312 and predominately arising from the respective extent of the magnetic domain 311.

In one embodiment, the second magnetic strip 330 generates at least a third magnetic domain 331 or 332, with each such magnetic domain having a respective extent. The superconductor strip 320 is sandwiched between the first and second magnetic strips 310 and 330 for undergoing the phase transition switching between the superconducting state 302 and the normal state 303 in response to the magnetic field controlled by the respective extents of the first and second magnetic domains 311 and 312 within the first magnetic strip 310 and the respective extent of each magnetic domain 331 or 332 within the second magnetic strip 330.

In a first state of the magnetic field at the superconductor strip 320 as shown in FIG. 3A, the superconductor strip 320 is sandwiched between the respective extent of the magnetic domain 312 of the first magnetic strip 310 and the respective extent of the magnetic domain 331 of the second magnetic strip 330, with the first state of the magnetic field having a diminished strength because the magnetic domain 312 opposes the magnetic domain 331 through the superconductor strip 320. In a second state of the magnetic field at the superconductor strip 320 as shown in FIG. 3B, the superconductor strip 320 is sandwiched between the respective extent of the magnetic domain 311 of the first magnetic strip 310 and the respective extent of the magnetic domain 331 of the second magnetic strip 330, with the second state of the magnetic field having an enhanced strength because the magnetic domain 311 supports the magnetic domain 331 through the superconductor strip 320. The magnetic field having the diminished strength at the superconductor strip 320 switches the superconductor strip 320 into the superconducting state 302, and the magnetic field having the enhanced strength at the superconductor strip 320 switches the superconductor strip 320 into the normal state 303.

In one embodiment, the second magnetic strip 330 has a static configuration of its magnetic domains 331 and 332. For example, an integrated circuit includes many instances of the cryogenic analog switch circuit 300, with the second magnetic strip 330 of each such instance connected in series between a power supply and ground, and with the combined resistance from all of the second magnetic strips 330 sufficiently high as to draw negligible current from the power supply.

However, in another embodiment the second magnetic strip 330 has a dynamic configuration of its magnetic domains 331 and 332. The second magnetic strip 330 generates the third magnetic domain 331 and a fourth magnetic domain 332 separated by a second domain wall 333. In response to a second current 334 through the second magnetic strip 330, the second domain wall 333 moves to change the respective extent of the third magnetic domain 331 and the respective extent of the fourth magnetic domain 332 within the second magnetic strip 330. The superconductor strip 320 undergoes the phase transition switching between the superconducting state 302 and the normal state 303 in response to the magnetic field controlled by the respective extents of the first and second magnetic domains 311 and 312 and the respective extents of the third and fourth magnetic domains 331 and 332. It will be appreciated that this embodiment behaves similar to an exclusive-or gate, yielding the superconducting state 302 if the currents 314 and 334 flow in different directions through the cryogenic analog switch circuit 300, and yielding the normal state 303 if the currents 314 and 334 flow in the same direction through the cryogenic analog switch circuit 300.

In an embodiment with many instances of the cryogenic analog switch circuit 300, each cryogenic analog switch circuit 300 acts similar to a transistor in CMOS logic, but with important advantages. In CMOS logic, the positive and negative types of transistors require differently doped regions with distinct fabrication steps that usually result in asymmetry between positive and negative types of transistors. In contrast, the direction of current flow of a static bias magnetic strip 330 symmetrically determines whether the cryogenic analog switch circuit 300 has a positive or a negative type without extra fabrication steps. In addition as mentioned above, complex gates, such as exclusive-or gates, are achieved when inputs are applied to both magnetic strips 310 and 330. In CMOS logic, typically both a positive and a negative transistor are simultaneously conductive briefly during switching transitions, resulting in extra power dissipation. When a single magnetic strip crosses over both one superconductor strip biased as a positive type and another superconductor strip biased as a negative type, the domain wall propagates in sequence over these two superconductor strips, such that break-before-make switching is achievable to reduce power dissipation. Make-before-break switching is also achievable if desired.

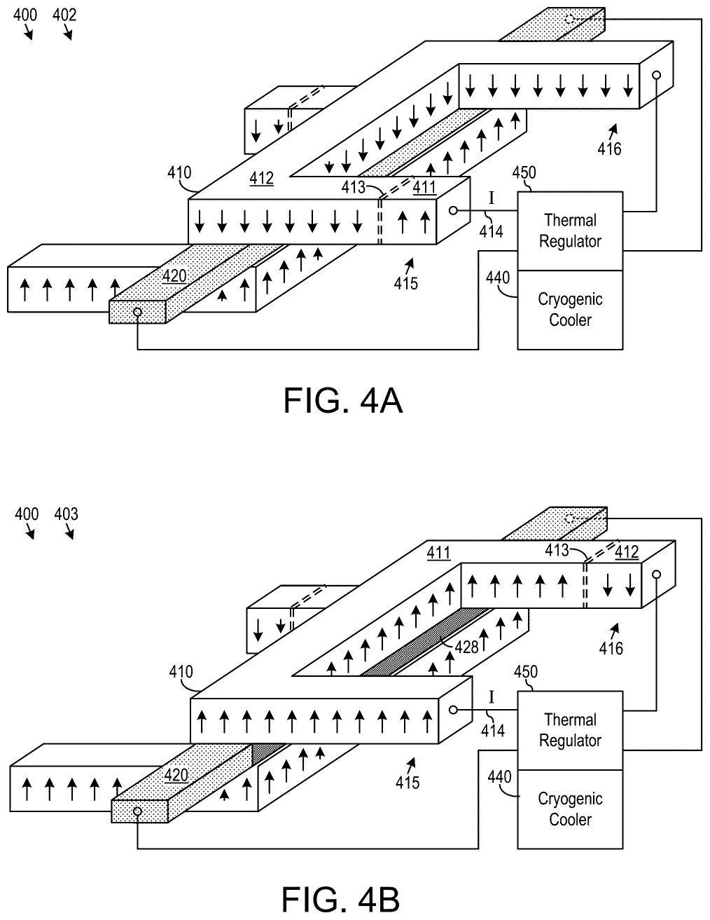

FIG. 4A-B are perspective views of a cryogenic analog switch circuit 400 in respective states 402 and 403 in accordance with an embodiment of the invention. As shown in FIG. 4B, the superconductor strip 420 has a longer dark-shaded portion 428 in the resistive normal state 403 as compared with the corresponding portion 328 of FIG. 3B. This increases the difference between the resistance through the superconductor strip 420 in the normal state 403 and the zero resistance through the superconductor strip 420 in the superconducting state 402.

The magnetic strip 410 crosses the superconductor strip 420 with overhangs 415 and 416 beyond a major face of the superconductor strip 420. While the magnetic domain 412 nearly spans the length of the magnetic strip 410 as shown in FIG. 4A, the domain wall 413 is disposed within the overhang 415 of the magnetic strip 410. While the magnetic domain 411 nearly spans the length of the magnetic strip 410 as shown in FIG. 4B, the domain wall 413 is disposed within the overhang 416 of the magnetic strip 410.

The cryogenic analog switch circuit 400 includes a cryogenic cooler 440 thermally coupled to the superconductor strip 420 for regulating an operating temperature of the cryogenic analog switch circuit 400 to maintain the superconductor strip 420 at the operating temperature below a critical temperature between the superconducting state and the normal state of the superconductor strip 420 during an absence of any magnetic field. The cryogenic cooler 440 maintains the superconductor strip 420 at the operating temperature below the critical temperature so that the phase transition between the superconducting state 402 and the normal state 403 occurs in response to the magnetic field having a strength approximately halfway between a minimum strength of FIG. 4A and a maximum strength of FIG. 4B for the magnetic field achieved at the superconductor strip 420 at extremes of the respective extents of the first and second magnetic domains 411 and 412 in response to the current on line 414 through the magnetic strip 410.

The cryogenic analog switch circuit 400 further includes a thermal regulator circuit 450 for varying the respective extents of the first and second magnetic domains 411 and 412 between the extremes of FIG. 4A-B with a fifty percent duty cycle and for adjusting the operating temperature until the phase transition between the superconducting state 402 and the normal state 403 is detected to also have a fifty percent duty cycle. Although the cryogenic analog switch circuit 400 is not available for other logic switching, an integrated circuit with many instances of the cryogenic analog switch circuit 400 need have only one of these instances dedicated to switching controlled by the thermal regulator circuit 450 to achieve equalized switching between the superconducting state 402 and the normal state 403 for all of the instances of the cryogenic analog switch circuit 400.

From the above description of Cryogenic Analog Switch Circuit, it is manifest that various techniques may be used for implementing the concepts of cryogenic analog switch circuits 100, 300, and 400 without departing from the scope of the claims. The described embodiments are to be considered in all respects as illustrative and not restrictive. The cryogenic analog switch circuits 100, 300, and 400 disclosed herein may be practiced in the absence of any element that is not specifically claimed and/or disclosed herein. It should also be understood that each of cryogenic analog switch circuits 100, 300, or 400 is not limited to the particular embodiments described herein, but is capable of many embodiments without departing from the scope of the claims.

We claim:

1. A cryogenic analog switch circuit, comprising:
a magnetic strip for generating a first and second magnetic domain separated by a domain wall, wherein, in response to a current through the magnetic strip, the domain wall moves to change respective extents of the first and second magnetic domains within the magnetic strip; and
a superconductor strip disposed adjacent the magnetic strip for undergoing a phase transition switching between a superconducting state and a normal state in response to a magnetic field controlled by the respective extents of the first and second magnetic domains within the magnetic strip.

2. The cryogenic switch circuit of claim 1, wherein the cryogenic analog switch circuit is closed when the superconductor strip is in the superconducting state, and the cryogenic analog switch circuit is open when the superconductor strip is in the normal state.

3. The cryogenic analog switch circuit of claim 2, wherein:
the superconductor strip spans between two terminals;
a voltage across the two terminals is zero when the cryogenic analog switch circuit is closed with the superconductor strip in the superconducting state; and
the voltage across the two terminals is non-zero when the cryogenic analog switch circuit is open with the superconductor strip in the normal state.

4. The cryogenic analog switch circuit of claim 1, wherein the superconducting state and the normal state of the superconductor strip are each maintained stored within the cryogenic analog switch circuit as long as the current through the magnetic strip is zero current.

5. The cryogenic analog switch circuit of claim 1, wherein:
the magnetic strip is uniaxially anisotropic to predispose the first and second domains becoming magnetized in opposite directions perpendicular to a major face of the magnetic strip;
when the current moves the domain wall so that the respective extent of the first magnetic domain predominates across the major face of the magnetic strip, the superconductor strip adopts the superconductive state because the first magnetic domain causes the magnetic field at the superconductor strip to have a weak strength that does not penetrate through the superconductor strip; and
when the current moves the domain wall so that the respective extent of the second magnetic domain predominates across the major face of the magnetic strip, the superconductor strip adopts the normal state because the second magnetic domain causes the magnetic field at the superconductor strip to have an enhanced strength that penetrates through the superconductor strip.

6. The cryogenic analog switch circuit of claim 5, wherein
the major face of the magnetic strip is disposed adjacent a major face of the superconductor strip;
the magnetic strip crosses the superconductor strip with a first and second overhang beyond the major face of the superconductor strip;
while the first magnetic domain predominates across the major face of the magnetic strip, the domain wall is disposed within the second overhang of the magnetic strip; and
while the second magnetic domain predominates across the major face of the magnetic strip, the domain wall is disposed within the first overhang of the magnetic strip.

7. The cryogenic analog switch circuit of claim 1, wherein:
the respective extents of the first and second magnetic domains together span a length of the magnetic strip;
the current in a first direction along the length moves the domain wall until the first magnetic domain nearly spans the length of the magnetic strip; and
the current in an opposite second direction along the length moves the domain wall until the second magnetic domain nearly spans the length of the magnetic strip.

8. The cryogenic analog switch circuit of claim 7, wherein:
the superconductor strip is in the superconducting state under the magnetic field driven from the first magnetic domain while the first magnetic domain nearly spans the length of the magnetic strip; and
the superconductor strip is in the normal state under the magnetic field driven from the second magnetic domain while the second magnetic domain nearly spans the length of the magnetic strip.

9. The cryogenic analog switch circuit of claim 8, further comprising:
a magnetic bias for opposing the first magnetic domain and for supporting the second magnetic domain, wherein,
the first magnetic domain nearly spanning the length of the magnetic strip and the magnetic bias together generate the magnetic field having a diminished strength because the magnetic bias opposes the first magnetic domain,
the second magnetic domain nearly spanning the length of the magnetic strip and the magnetic bias together generate the magnetic field having an enhanced strength because the magnetic bias supports the second magnetic domain, and
the magnetic field having the diminished strength at the superconductor strip switches the superconductor strip into the superconducting state, and the magnetic field having the enhanced strength at the superconductor strip switches the superconductor strip into the normal state.

10. The cryogenic analog switch circuit of claim 9, wherein:
the magnetic strip is uniaxially anisotropic to predispose the first and second magnetic domains becoming magnetized in opposite directions perpendicular to a major face of the magnetic strip;
the major face of the magnetic strip is disposed adjacent a major face of the superconductor strip;
the magnetic strip crosses the superconductor strip with a first and second overhang beyond the major face of the superconductor strip;
while the first magnetic domain nearly spans the length of the magnetic strip, the domain wall is disposed within the second overhang of the magnetic strip; and
while the second magnetic domain nearly spans the length of the magnetic strip, the domain wall is disposed within the first overhang of the magnetic strip.

11. The cryogenic analog switch circuit of claim 1, wherein the superconductor strip switches between the superconducting state and the normal state in response to the magnetic field at the superconductor strip switching between a first and second state in response to the domain wall moving in response to the current through the magnetic strip, the first state arising more from the first magnetic domain than the second magnetic domain and the second state arising more from the second magnetic domain than the first magnetic domain.

12. The cryogenic analog switch circuit of claim 1, wherein the superconductor strip switches between the superconducting state and the normal state in response to the magnetic field at the superconductor strip switching between predominately arising from the respective extent of the first magnetic domain and predominately arising from the respective extent of the second magnetic domain.

13. The cryogenic analog switch circuit of claim 1, wherein the magnetic strip is a first magnetic strip, the cryogenic analog switch circuit further comprising:
a second magnetic strip for generating at least a third magnetic domain each with a respective extent,
wherein the superconductor strip is sandwiched between the first and second magnetic strips for undergoing the phase transition switching between the superconducting state and the normal state in response to the magnetic field controlled by the respective extents of the first and second magnetic domains within the first magnetic strip and the respective extent of each of the at least one third magnetic domain within the second magnetic strip.

14. The cryogenic analog switch circuit of claim 13, wherein:
in a first state of the magnetic field at the superconductor strip, the superconductor strip is sandwiched between the respective extent of the first magnetic domain of the first magnetic strip and the respective extent of the third magnetic domain of the second magnetic strip, with the first state of the magnetic field having a diminished strength because the first magnetic domain opposes the third magnetic domain through the superconductor strip;
in a second state of the magnetic field at the superconductor strip, the superconductor strip is sandwiched between the respective extent of the second magnetic domain of the first magnetic strip and the respective extent of the third magnetic domain of the second magnetic strip, with the second state of the magnetic field having an enhanced strength because the second magnetic domain supports the third magnetic domain through the superconductor strip; and
the magnetic field having the diminished strength at the superconductor strip switches the superconductor strip into the superconducting state, and the magnetic field having the enhanced strength at the superconductor strip switches the superconductor strip into the normal state.

15. The cryogenic analog switch circuit of claim 13, wherein:
the second magnetic strip is for generating the third magnetic domain and a fourth magnetic domain separated by a second domain wall, wherein, in response to a second current through the second magnetic strip, the second domain wall moves to change the respective extent of the third magnetic domain and the respective extent of the fourth magnetic domain within the second magnetic strip; and
the superconductor strip is for undergoing the phase transition switching between the superconducting state and the normal state in response to the magnetic field controlled by the respective extents of the first and second magnetic domains, the respective extent of the third magnetic domain, and the respective extent of the fourth magnetic domain.

16. The cryogenic analog switch circuit of claim 1, further comprising an insulator disposed between the magnetic strip and the superconductor strip for electrically and thermally isolating the magnetic strip and the superconductor strip from each other.

17. The cryogenic analog switch circuit of claim 16, further comprising a cryogenic cooler thermally coupled to the superconductor strip for regulating an operating temperature of the superconductor strip to maintain the superconductor strip at the operating temperature slightly below a critical temperature between the superconducting state and the normal state of the superconductor strip during an absence of the magnetic field.

18. The cryogenic analog switch circuit of claim 17, wherein the cryogenic cooler is for maintaining the superconductor strip at the operating temperature slightly below the critical temperature so that the phase transition between the superconducting state and the normal state occurs in response to the magnetic field having a strength approximately halfway between a minimum strength and a maximum strength of the magnetic field achieved at the superconductor strip at extremes of the respective extents of the first and second magnetic domains in response to the current through the magnetic strip.

19. The cryogenic analog switch circuit of claim 18, further comprising a thermal regulator circuit for varying the respective extents of the first and second magnetic domains between the extremes with a fifty percent duty cycle and for adjusting the operating temperature until the phase transition between the superconducting state and the normal state is detected to also have a fifty percent duty cycle.

20. The cryogenic switch circuit of claim 1, wherein the domain wall moves in response to the current through the magnetic strip at a speed measured in kilometers per second, and a distance the domain wall moves to accomplish switching the superconductor strip between the superconducting state and the normal state is measured in tens of nanometers, such that a transition time from the normal state to the superconducting state and another transition time from the superconducting state to the normal state are each measured in tens of picoseconds.
